(19) United States
(12) Patent Application Publication
(10) Pub. No.: US 2024/0377180 A1
(43) Pub. Date: Nov. 14, 2024

(54) FLEXIBLE SENSOR AND METHOD FOR MANUFACTURING FLEXIBLE SENSOR

(71) Applicants: NATIONAL INSTITUTE OF ADVANCED INDUSTRIAL SCIENCE AND TECHNOLOGY, Tokyo (JP); NIKON CORPORATION, Tokyo (JP)

(72) Inventors: Shusuke Kanazawa, Tsukuba-shi (JP); Motoshi Itagaki, Tsukuba-shi (JP); Shohei Koizumi, Atsugi-shi (JP); Yoshiaki Kito, Kamakura-shi (JP); Katsuhiro Hatayama, Tokyo (JP); Changhoon Shim, Fujisawa-shi (JP)

(73) Assignees: NATIONAL INSTITUTE OF ADVANCED INDUSTRIAL SCIENCE AND TECHNOLOGY, Tokyo (JP); NIKON CORPORATION, Tokyo (JP)

(21) Appl. No.: 18/779,202

(22) Filed: Jul. 22, 2024

Related U.S. Application Data
(63) Continuation of application No. PCT/JP2022/043157, filed on Nov. 22, 2022.

(30) Foreign Application Priority Data
Jan. 25, 2022 (JP) 2022-009277

(51) Int. Cl. G01B 7/16; H10N 79/00

(52) U.S. Cl. CPC G01B 7/18; H10N 79/00

(57) ABSTRACT

A flexible sensor includes a main substrate having flexibility, a transistor over the main substrate, a support substrate over the transistor, wherein the support substrate has flexibility and at least an outer surface of the support substrate comprises a material having electric insulation, and a variable resistance part over a first surface which is an upper surface of the support substrate, in which a resistance value of the variable resistance part changes according to strain of the variable resistance part.

### CROSS-REFERENCE TO RELATED APPLICATION

Priority is claimed on Japanese Patent Application No. 2022-009277, filed on Jan. 25, 2022. The present application is a continuation application of International Application PCT/JP2022/043157, filed on Nov. 22, 2022. The contents of the above applications are incorporated herein.

### BACKGROUND

### Technical Field

The present invention relates to a flexible sensor and a method for manufacturing the flexible sensor.

A flexible sensor having flexibility is known. For example, Japanese Unexamined Patent Application, First Publication No. H11-241903 discloses a strain sensor as such a flexible sensor. The strain sensor is formed of a layered formation on a flexible substrate, with conductive particles dispersed in a polymer material such as plastic, rubber, or the like. Then, strain caused by deformation of an object to be measured (a steel structure or a reinforced concrete structure) to which a substrate is attached is measured using characteristics that the electric resistance of the formation changes due to elongation of the formation according to elongation of the substrate. Such a flexible sensor can be used not only to measure 1-dimensional expansion and contraction of an object to be measured but also to conveniently measure 2-dimensional strain (deformation) of a surface of the object to be measured or 2-dimensional flow velocity distribution of a fluid by improving detection accuracy or detection sensitivity.

### SUMMARY

One aspect of a flexible sensor of the present invention includes a main substrate having flexibility; a transistor over the main substrate; a support substrate over the transistor, wherein the support substrate has flexibility and at least an outer surface of the support substrate comprises a material having electric insulation; and a variable resistance part over a first surface which is an upper surface of the support substrate, in which a resistance value of the variable resistance part changes according to strain of the variable resistance part.

In addition, one aspect of a method for manufacturing a flexible sensor of the present invention includes a process of providing a variable resistance part, over a first surface of a support substrate which has flexibility and at least an outer surface of the support substrate comprises a material having electric insulation, which has a resistance value that changes according to strain of the variable resistance part; a process of forming a transistor over a main substrate having flexibility; a process of providing an adhesive layer over a second surface of the support substrate opposite to the first surface after the process of providing the variable resistance part; and a process of attaching the adhesive layer to the main substrate on a side that the transistor is formed after the process of providing the adhesive layer.

### BRIEF DESCRIPTION OF THE DRAWINGS

FIG. 1 is a perspective view showing an embodiment of a flexible sensor of the present invention.

FIG. 2 is a plan view showing a sensor main body of the embodiment.

FIG. 3 is a circuit diagram showing a part of a circuit configuration of the flexible sensor.

FIG. 4 is a circuit diagram showing a circuit configuration of a sensor element in the sensor main body.

FIG. 5 is a cross-sectional view showing a part of the sensor main body.

FIG. 6 is a cross-sectional view showing a part of the sensor main body and a cross-sectional view along line VI-VI in FIG. 5.

FIG. 7 is a cross-sectional view showing a part of the sensor main body and a cross-sectional view along line VII-VII in FIG. 5.

FIG. 8 is a view schematically showing a configuration of a controller of the flexible sensor.

FIG. 9 is a flowchart showing a method for manufacturing a flexible sensor of an embodiment of the present invention.

FIG. 10 is a cross-sectional view for describing a resistor installing process of the method for manufacturing the flexible sensor.

FIG. 11 is a cross-sectional view for describing an adhesive layer installing process of the method for manufacturing the flexible sensor.

FIG. 12 is a cross-sectional view for describing a through-hole forming process of the method for manufacturing the flexible sensor.

FIG. 13 is a cross-sectional view for describing an adhesion process of the method for manufacturing the flexible sensor.

FIG. 14 is a cross-sectional view for describing a wiring process of the method for manufacturing the flexible sensor.

FIG. 15 is a cross-sectional view for describing a coating process of the method for manufacturing the flexible sensor.

### DESCRIPTION OF THE EMBODIMENTS

Hereinafter, a flexible sensor and a method for manufacturing the flexible sensor (hereinafter, also simply referred to as a manufacturing method) according to an embodiment of the present invention will be described with reference to the accompanying drawings.

Further, the scope of the present invention is not limited to the following embodiment and may be arbitrarily modified without departing from the technical scope of the present invention. In addition, in the following drawings, in order to make each component easier to understand, the scale and number of each structure may be different from the scale and number of the actual structure.

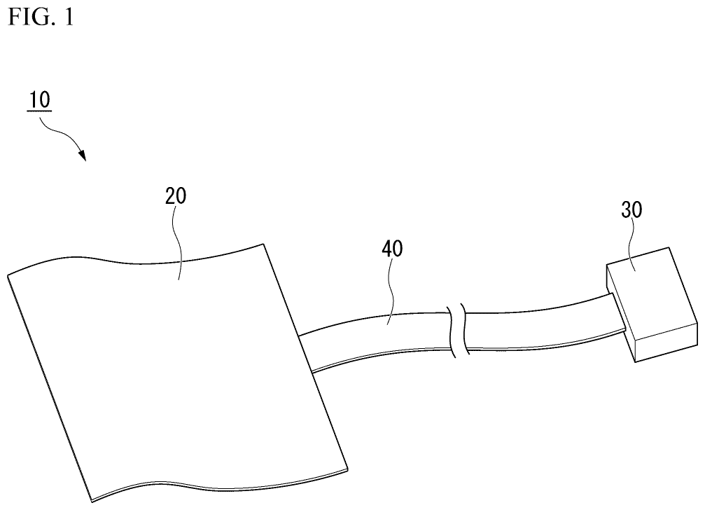

As shown in FIG. 1, a flexible sensor 10 of the embodiment is, for example, a strain sensor configured to measure strain of an object to be measured. The flexible sensor 10 according to the embodiment includes a sensor main body 20, a wiring part 40, and a controller (measurement part) 30.

The sensor main body 20 is adhered to an object to be measured, strain of which is measured.

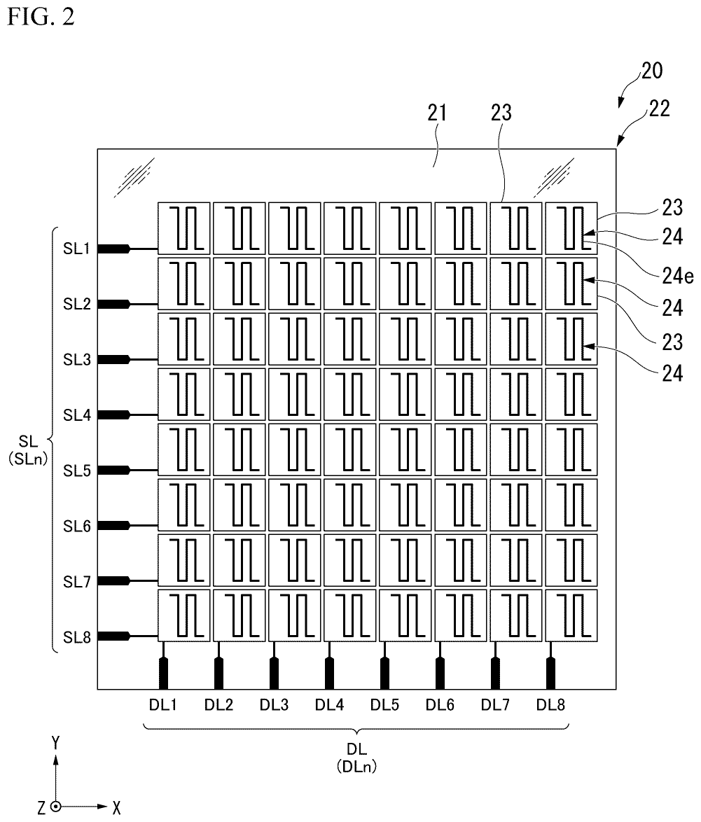

The sensor main body 20 has flexibility. The sensor main body 20 has a main substrate 21 and a sensor part 22, as shown in FIG. 2. The main substrate 21 has flexibility. In this specification, the flexibility of the main substrate 21 is the property of being able to bend and undergo elastic deformation without disconnecting or breaking even when a force equivalent to its own weight is applied. In addition, flexibility also includes the ability to bend under the force of its own weight.

Accordingly, the main substrate 21 is formed of a base material having stiffness (a Young's modulus) that, when it is bent from a flat state within the range of elastic deformation by an external force, allows it to return to its original flat state when the external force is removed. Further, the flexibility of the main substrate 21 can vary depending on the material, size and thickness of the main substrate 21, environmental factors such as a temperature, or the like.

The same applies to flexibility of a support substrate 28, which will be described below.

The main substrate 21 preferably has electric insulation.

As the base material of the main substrate 21, for example, a resin film such as polyacrylate, polycarbonate, polyurethane, polystyrene, cellulose polymer, polyolefin, polyamide, polyimide, polyester, polyphenylene, polyethylene, polyethylene terephthalate (PET), polyethylene naphthalate (PEN), polypropylene, ethylene vinyl copolymer, polyvinyl chloride, or the like, glass, sapphire, metal, cellulose nanofiber, or the like made into a thin plate with a thickness of tens of μm (micrometers) to several hundred μm can be used.

The main substrate 21 according to the embodiment is, for example, a square-shaped resin film. Further, a shape of the main substrate 21 is not limited to the square shape but may be a triangular shape, a rectangular shape, a diamond shape, a polygonal shape with or more sides, a circular shape, an elliptical shape, or the like.

In each of the drawings, an X-axis direction, a Y-axis direction, and a Z-axis direction are shown appropriately with reference to the main substrate 21 when it is not deformed. The Z-axis direction indicates a thickness direction of the main substrate 21. The X-axis direction indicates a direction parallel to one side of the square-shaped main substrate 21. The Y axis indicates a direction parallel to one side of the square-shaped main substrate 21 extending in a direction different from the X-axis direction. The X-axis direction, the Y-axis direction and the Z-axis direction are perpendicular to each other.

In the following description, a direction parallel to the Z-axis direction is referred to as “a thickness direction.” A direction parallel to the X-axis direction is referred to as “a first direction,” and a direction parallel to the Y-axis direction is referred to as “a second direction.” In addition, a positive side (+Z side) in the Z-axis direction is referred to as “an upper side,” and a negative side (−Z side) in the Z-axis direction is referred to as “a lower side.” In addition, a positive side (+X side) in the X-axis direction is referred to as “one side in the first direction,” and a negative side (−X side) in the X-axis direction is referred to as “the other side in the first direction.” In addition, a positive side (+Y side) in the Y-axis direction is referred to as “one side in the second direction,” and a negative side (−Y side) in the Y-axis direction is referred to as “the other side in the second direction.”

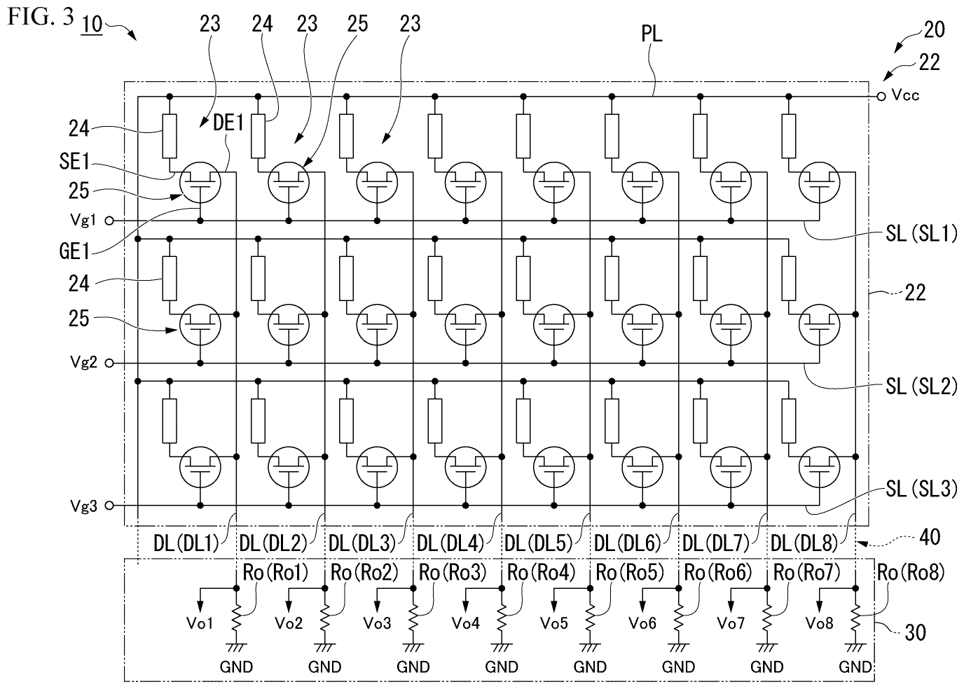

The sensor part 22 is a part configured to detect strain of an object to be measured, to which the sensor main body 20 is attached. The sensor part 22 is provided on a surface of the main substrate 21 on an upper side (+Z side). As shown in FIG. 2 and FIG. 3, the sensor part 22 has a plurality of sensor elements 23, a plurality of scan lines SL, a plurality of signal lines DL, and a power electrode (a wiring for a power supply) PL.

The sensor part 22 according to the embodiment is an active matrix type sensor part in which the plurality of sensor elements 23 are disposed in a matrix. The plurality of sensor elements 23 according to the embodiment are disposed in a matrix in the first direction and the second direction. In the example shown in FIG. 2, the sensor elements 23 are disposed in a matrix of 8 rows and 8 columns, i.e., a total of 64 sensor elements are provided.

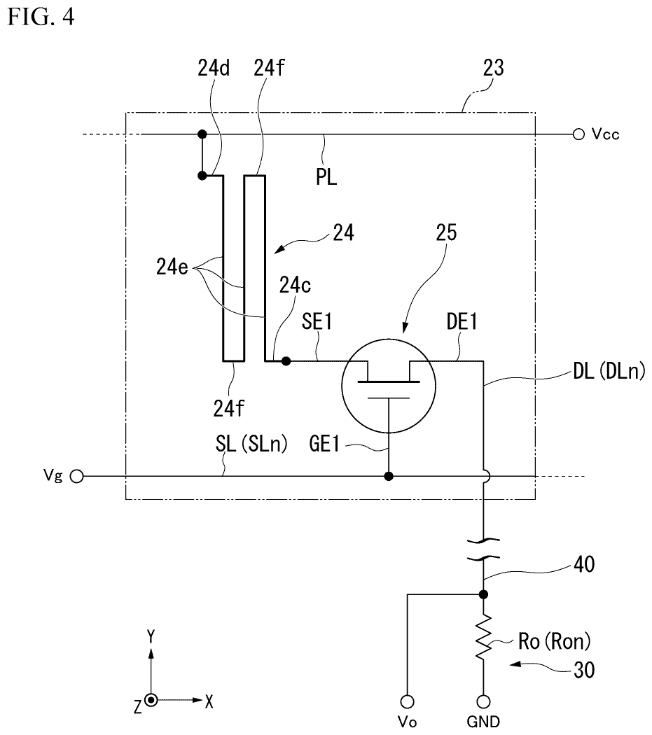

The plurality of sensor elements 23 are provided on the main substrate 21. Each of the sensor elements 23 has a transistor 25 and a variable resistance part 24, as shown in FIG. 3 and FIG. 4.

The transistor 25 is provided on an end portion of the main substrate 21 near the support substrate 28, which will be described below. The transistor 25 is a field effect transistor (FET) having a gate electrode GE1, a source electrode SE1, and a drain electrode DE1. The transistor 25 according to the embodiment is a thin film transistor (TFT). The transistor 25 is, for example, an organic thin film transistor (OTFT).

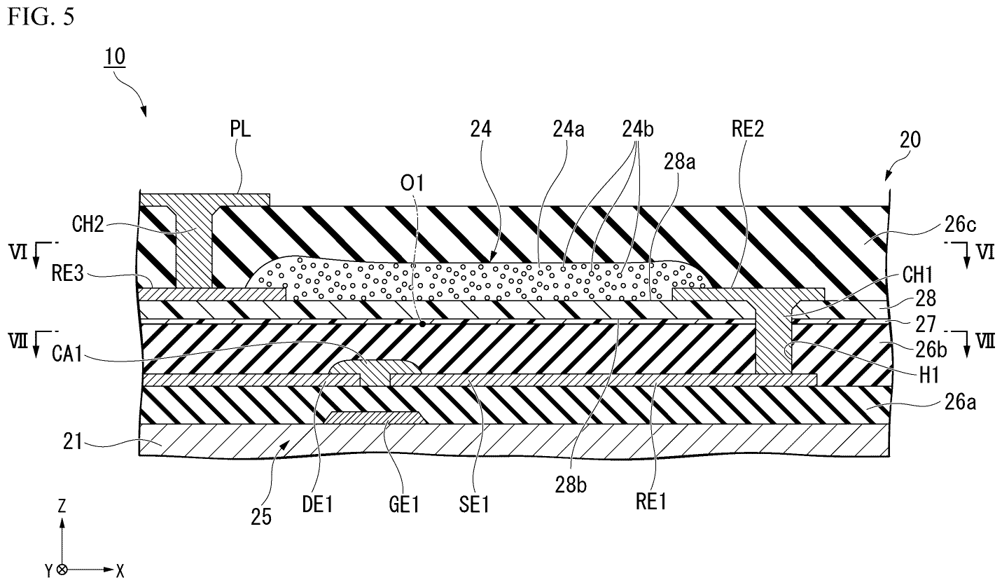

The transistor 25 according to the embodiment has a P type channel CA1 as shown in FIG. 5. In the embodiment, a material of the channel CA1 is, for example, an organic semiconductor.

As the organic semiconductor, for example, copper phthalocyanine (CuPc), pentacene, rubrene, tetracene, 6,13-bis(triisopropylsilylethynyl)pentacene (TIPS pentacene), poly(3-hexylthiophene-2,5-diyl) (P3HT), or the like can be used. The organic semiconductor that can be used as the material of the channel CA1 is not limited to the above-mentioned material.

Further, the material of the channel CA1 may be an inorganic semiconductor. As the inorganic semiconductor, for example, an oxide including zinc oxide (ZnO), In, Ga and Zn (InGaZnO₄:IGZO), amorphous silicon, low temperature polysilicon, or the like can be used. The inorganic semiconductor that can be used as the material of the channel CA1 is not limited to the above-mentioned material.

The channel CA1 connects the source electrode SE1 and the drain electrode DE1. The transistor 25 according to the embodiment is, for example, a bottom gate type and a bottom contact type transistor.

The source electrode SE1 and the drain electrode DE1 according to the embodiment are arranged in the first direction. The source electrode SE1 is located at, for example, one side (+X side) of the drain electrode DE1 in the first direction. The transistor 25 according to the embodiment functions as an active matrix switching element configured to select the variable resistance part 24 to be measured in the variable resistance parts 24 that are two-dimensionally arranged in the first direction and the second direction at predetermined intervals.

The variable resistance part 24 is a portion that varies a resistance value according to the strain (expansion and contraction due to deflection of the main substrate 21 in the thickness direction). The variable resistance part 24 according to the embodiment has a film shape formed on a surface on an upper side (+Z side) of the support substrate 28, which will be described below, as shown in FIG. 5.

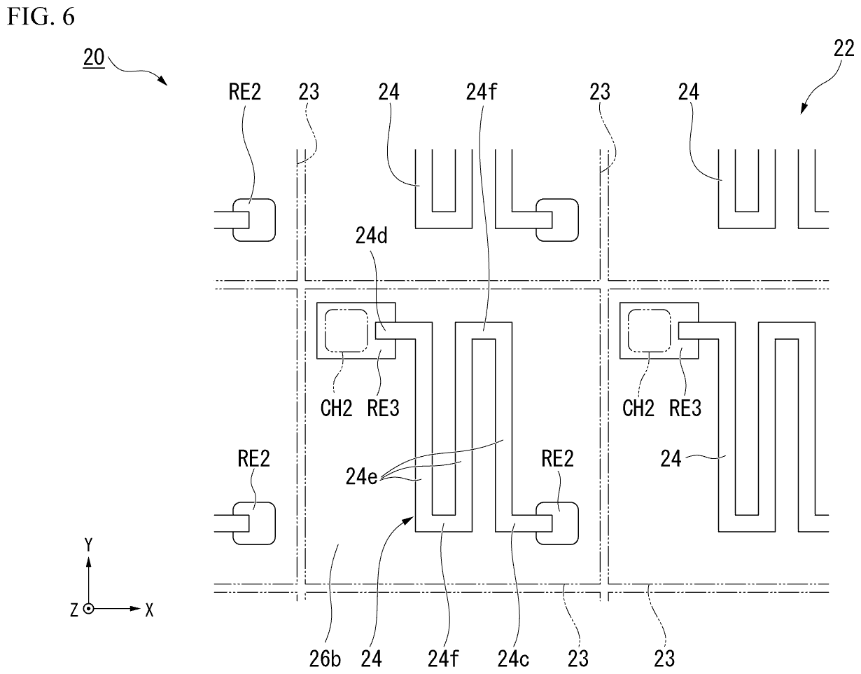

The shape of the variable resistance part 24 is not limited. For example, the variable resistance part 24 has a rectangular wave shape when seen in a plane parallel to the XY plane as shown in FIG. 4 and FIG. 6. The variable resistance part 24 has a plurality of extension parts 24e, a connecting part 24f, and connection parts 24c and 24d.

The extension parts 24e extend in one direction. The plurality of extension parts 24e in one of the variable resistance parts 24 extend in the same direction and are arranged in a direction perpendicular to the extending direction at intervals.

The plurality of extension parts 24e according to the embodiment extend in the second direction. That is, the direction in which the extension parts 24e extend is perpendicular to the direction in which the source electrode SE1 and the drain electrode DE1 are arranged.

The extension parts 24e according to the embodiment extend in the second direction even in the variable resistance parts 24 of both sensor elements 23. That is, in the plurality of sensor elements 23 included in the sensor part 22, the extension parts 24e of the variable resistance part 24 extend in the same direction.

Further, “the plurality of extension parts extending in the same direction” in the specification includes a case in which the plurality of extension parts extend in substantially the same direction, in addition to the case in which the plurality of extension parts extend in strictly the same direction.

As an example, “the plurality of extension parts extending in substantially the same direction” includes a case in which a deviation between the direction in which one extension part extends and the direction in which the other extension part extends is within about 10 degrees.

For example, three extension parts 24e are provided for each variable resistance part 24. The plurality of extension parts 24e according to the embodiment are arranged in the first direction at equal intervals. The interval between the extension parts 24e is smaller than the length of the extension parts 24e. The length of the extension parts 24e according to the embodiment is a dimension of the extension parts 24e in the second direction.

Further, “the plurality of extension parts being disposed at equal intervals” in this specification also includes a case in which intervals between the extension parts are substantially the same, in addition to the case in which the intervals between the extension parts are strictly the same.

As an example, “the intervals between the extension parts are substantially the same” includes a case in which a difference between the interval of one pair of extension parts and the interval of the other pair of extension parts is within about 10%.

The connecting part 24f extends in the first direction and connects end portions of the neighboring extension parts 24e. For example, two connecting parts 24f are provided.

One of the connecting parts 24f connects (i) end portion of the center extension part 24e and (ii) end portion of the extension part 24e located at one side (+X side) in the first direction, at one side (+Y side) in the second direction. The other connecting part 24f connects (i) end portion of the center extension part 24e and (ii) end portion of the extension part 24e located at the other side (−X side) in the first direction, at the other side (−Y side) in the second direction. Accordingly, the variable resistance part 24 is configured in a rectangular wave shape in which the neighboring extension parts 24e are connected to each other.

The length of the connecting part 24f is the same as the interval between the extension parts 24e and smaller than the length of the extension parts 24e. The length of the connecting part 24f according to the embodiment is a dimension of the connecting part 24f in the first direction.

The connection part 24c is one end portion of the variable resistance part 24. The connection part 24c extends toward one side in the first direction from an end portion on the other side (−Y side) in the second direction of the extension part 24e which is located at one side (+X side) in the first directions.

As shown in FIG. 4, the connection part 24c is connected to the source electrode SE1 of the transistor 25. Accordingly, the variable resistance part 24 is connected to the source electrode SE1 of the transistor 25. More specifically, the variable resistance part 24 is connected to the source electrode SE1 in series.

The connection part 24d is the other end portion of the variable resistance part 24. As shown in FIG. 6, the connection part 24d extends toward the other side in the first direction from an end portion on one side (+Y side) in the second direction of the extension part 24e which is located on the other side (−X side) in the first direction. As shown in FIG. 4, the connection part 24d is connected to the power electrode PL. Accordingly, the variable resistance part 24 is connected to the power electrode PL.

The variable resistance part 24 according to the embodiment has an insulating body 24a, and a plurality of conductive particles 24b distributed in the insulating body 24a as shown in an enlarged form in FIG. 5.

The material of the insulating body 24a is not particularly limited as long as the material has insulation, and for example, it may be a resin material such as a plastic or the like, or a polymer material such as rubber or the like. The material of the insulating body 24a according to the embodiment is an energy curable resin. The energy curable resin is, for example, a thermosetting resin, a photocurable resin, or the like.

The material of the conductive particles 24b is not particularly limited as long as the material has conductivity, and for example, it may be carbon (graphite), a metal, or the like.

A distance between the plurality of conductive particles 24b in the insulating body 24a changes when strain (expansion and contraction) occurs in the variable resistance part 24, and conductivity in the variable resistance part 24 changes. Accordingly, the resistance value of the variable resistance part 24 changes depending on its own strain.

Specifically, for example, when the strain in the direction in which the variable resistance part 24 is contracted occurs, by shortening the distance between the conductive particles 24b in the insulating body 24a, the contact interface between the conductive particles 24b increases, and the resistance value of the variable resistance part 24 decreases. Meanwhile, when the strain in the direction in which the variable resistance part 24 expands occurs, by increasing the distance between the conductive particles 24b in the insulating body 24a, the contact interface between the conductive particles 24b decreases, and the resistance value of the variable resistance part 24 increases.

For example, in the case in which the variable resistance part 24 is formed in a film shape on the support substrate 28 as in this embodiment, when the sensor elements 23 are bent downward (−Z side) to be convex, the variable resistance part 24 is strained in a contraction direction, and the resistance value of the variable resistance part 24 becomes smaller.

Meanwhile, when the sensor main body 20 is bent upward to be convex, the variable resistance part 24 is strained in the expansion direction, and the resistance value of the variable resistance part 24 increases.

For example, changes in the resistance value of the variable resistance part 24 change exponentially with respect to the expansion and contraction rate of the variable resistance part 24 within a certain range of expansion and contraction of the variable resistance part 24.

In addition, for example, when the variable resistance part 24 is contracted beyond a certain level, the resistance value of the variable resistance part 24 becomes hardly to change. This is because the distance between the conductive particles 24b will not become any shorter, and the resistance value will no longer become smaller. In addition, for example, when the variable resistance part 24 is stretched beyond a certain point, the resistance value of the variable resistance part 24 becomes hardly to change. This is because the distance between the conductive particles 24b becomes too long, and the resistance value of the variable resistance part 24 no longer increases.

Further, “the variable resistance part” in the specification may be made using sensor paint disclosed in, for example, Japanese Unexamined Patent Application, First Publication No. 2009-198482 and Japanese Unexamined Patent Application, First Publication No. 2009-198483. In addition, “the variable resistance part” in the specification may be made using pressure sensitive resistor paint disclosed in, for example, Japanese Unexamined Patent Application, First Publication No. S60-127603. “The variable resistance part” may be made using strain deformation resistance change rubber disclosed in Japanese Unexamined Patent Application, First Publication No. S62-12825, may be made using a resistance ink for strain gauge disclosed in Japanese Unexamined Patent Application, First Publication No. H07-243805, or may be made using ink formed of a polymer material in which conductive particles (graphite) are distributed, disclosed in Japanese Unexamined Patent Application, First Publication No. H11-241903.

In the variable resistance part 24, the extension parts 24e, the connecting part 24f, and the connection parts 24c and 24d can be formed of the same material. However, in the embodiment, since a portion required for measurement of strain (expansion and contraction) is the extension parts 24e, it is sufficient that at least the extension parts 24e have a structure in which the resistance value changes as described above, that is, a structure having the insulating body 24a and the conductive particles 24b.

That is, the connecting part 24f and the connection parts 24c and 24d may not include the insulating body 24a and the conductive particles 24b. The connecting part 24f and the connection parts 24c and 24d may be, for example, a thin film of a conductive material such as gold, silver, copper, aluminum, nickel-phosphorus, conductivity polymer, or the like.

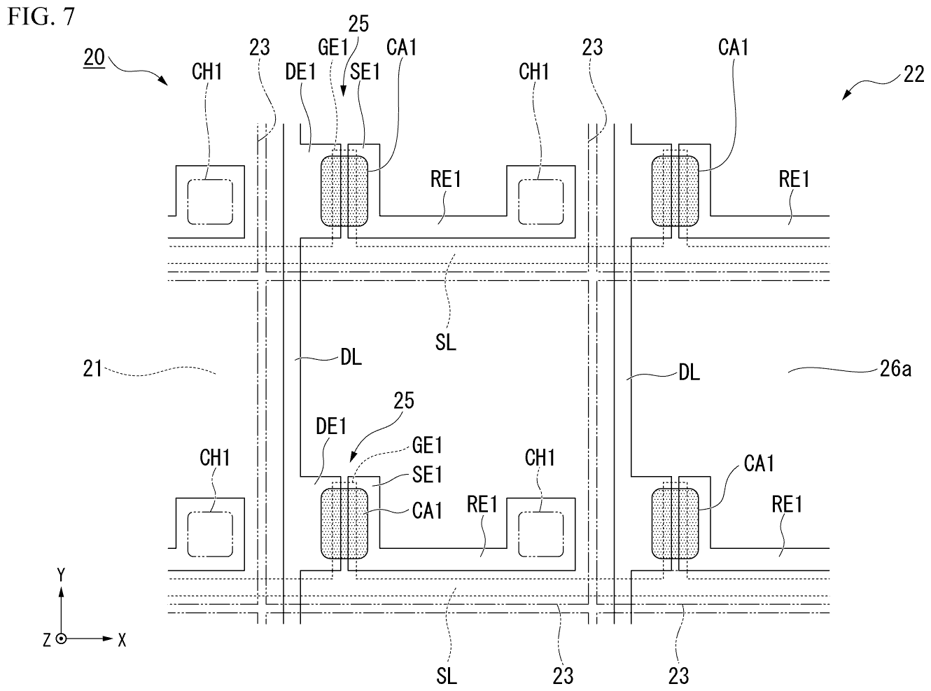

As shown in FIG. 7, the plurality of scan lines SL extend in the first direction. The plurality of scan lines SL are disposed at intervals in the second direction.

As shown in FIG. 2, in the embodiment, there are eight scan lines SL, i.e., scan lines SL1 to SL8. As shown in FIG. 3, the plurality of gate electrodes GE1 of the transistor 25 are connected to each of the scan lines SL. More specifically, the gate electrodes GE1 of the eight sensor elements 23 of each row of the sensor elements 23 disposed in eight rows and eight columns are connected to the scan lines SL1 to SL8, respectively.

As shown in FIG. 2, for example, end portions of the scan lines SL1 to SL8 on the other side (−X side) in the first direction are provided as terminal parts on the main substrate 21.

As shown in FIG. 7, the plurality of signal lines DL extend in the second direction. The plurality of signal lines DL are disposed at intervals in the first direction.

As shown in FIG. 2, in the embodiment, there are eight signal lines DL, i.e., signal lines DL1 to DL8. As shown in FIG. 3, the plurality of drain electrodes DE1 of the transistor 25 are connected to each of the signal lines DL. More specifically, the drain electrodes DE1 of the eight sensor elements 23 of each column of the sensor elements 23 disposed in eight rows and eight columns are connected to the signal lines DL1 to DL8, respectively.

As shown in FIG. 2, for example, end portions of the signal lines DL1 to DL8 on the other side (−Y side) in the second direction are provided as terminal parts on the main substrate 21.

Further, as shown in FIG. 5 and FIG. 7, each of the scan lines SL1 to SL8 is formed as the same layer on the surface of the main substrate 21 together with the gate electrode GE1 of each of the transistors 25, and each of the signal lines DL1 to DL8 is formed on a surface of an insulating film 26a laminated thereon together with the drain electrode DE1 and the source electrode SE1 of each of the transistors 25.

As shown in FIG. 3 and FIG. 4, the signal lines DL is connected to a fixed resistance part Ro provided on the controller 30 via the wiring part 40. The fixed resistance part Ro includes eight fixed resistance parts Ro1 to Ro8. Each of the fixed resistance parts Ro1 to Ro8 is connected to each of the signal lines DL1 to DL8. Each of the fixed resistance parts Ro1 to Ro8 are connected to a ground GND provided on the controller 30.

Further, in the following description, the scan lines SL1 to SL8 are also collectively referred to as the scan lines SLn. The signal lines DL1 to DL8 are also collectively referred to as the signal lines DLn, and the fixed resistance parts Ro1 to Ro8 are also collectively referred to as the fixed resistance part Ron.

In each of the scan lines SLn, the signal lines DLn, and the fixed resistance part Ron, “n” is an integer from 1 to 8.

The power electrode PL is an electrode to which a power supply potential of Vcc is supplied from the controller 30 via the wiring part 40. One end side of the variable resistance part 24 is connected to the power electrode PL. The source electrode SE1 of the transistor 25 is connected to the other end side of the variable resistance part 24. In the embodiment, each of the source electrodes SE1 of all the sensor elements 23 included in the sensor part 22 is connected to the power electrode PL via the variable resistance part 24, respectively.

The power electrode PL according to the embodiment is connected to the ground GND via the variable resistance part 24, the transistor 25, the signal lines DLn (n=1 to 8), the wiring part 40, and the fixed resistance part Ron (n=1 to 8). For this reason, a voltage corresponding to a potential difference between the power supply potential supplied to the power electrode PL and the ground GND, i.e., a power supply voltage Vcc is applied to the variable resistance part 24, the transistor 25, and the fixed resistance part Ron.

As shown in FIG. 5, in the embodiment, each part of the sensor part 22 described above is formed in a film shape, and the sensor part 22 is formed by laminating a plurality of films on the main substrate 21. Each part of the sensor part 22 formed in a film shape is formed by, for example, a wet method.

The sensor part 22 further has the insulating film 26a, an insulating film 26b, an insulating film (coating member) 26c, an adhesive layer 27, the support substrate 28, a contact hole (wiring) CH1, a contact hole CH2, and relay electrodes RE1, RE2 and RE3, in addition to the above-mentioned parts.

The material of the insulating films 26a, 26b and 26c is, for example, an insulating inorganic material such as silicon compound or the like. Further, in FIG. 7, the insulating film 26b is not shown. In FIG. 6, the insulating film 26c is not shown.

The scan lines SL, the signal lines DL, the power electrode (wiring for a power supply) PL, the gate electrode GE1, the source electrode SE1, the drain electrode DE1, the relay electrodes RE1, RE2 and RE3, and the like, are constituted by a thin film of a conductive material such as gold, silver, copper, aluminum, nickel-phosphorus, conductivity polymer, or the like.

As shown in FIG. 5 and FIG. 7, the gate electrode GE1, the scan lines SL, and the insulating film 26a are formed on an upper surface of the main substrate 21. The insulating film 26a covers the gate electrode GE1 from above. The gate electrode GE1 and the scan lines SL according to the embodiment is made by applying the same conductive material on the upper surface of the main substrate 21.

In the case of the application method, the gate electrode GE1 and the scan lines SL are made in an inkjet type, a screen printing type, or the like, using conductive ink containing conductive nano particles such as silver, gold, copper, or the like. In addition, after forming a metal thin film such as copper, nickel, gold, or the like, on the upper surface of the main substrate 21 uniformly, the gate electrode GE1 and the scan lines SL may be formed by an etching method of partially removing the metal thin film.

Further, when the base material of the main substrate 21 is a sheet of a conductive material such as a metal or the like, it is necessary to provide an insulating layer between the gate electrode GE1 and the main substrate 21 and between the scan lines SL and the main substrate 21.

The insulating layer may be the same material as or may be a material different from the insulating films 26a, 26b and 26c. In addition, the insulating layer may be provided on the entire surface on the main substrate 21, or may be provided in only a region corresponding to the gate electrode GE1 and the scan lines SL on the main substrate 21.

The source electrode SE1, the drain electrode DE1, the channel CA1, the signal lines DL, the relay electrode RE1, and the insulating film 26b are formed on the upper surface of the insulating film 26a. The insulating film 26b covers the source electrode SE1, the drain electrode DE1, the channel CA1, the signal lines DL, and the relay electrode RE1 from above.

The source electrode SE1, the drain electrode DE1, the signal lines DL, and the relay electrode RE1 according to the embodiment are made by applying the same conductive material (conductive ink or the like) on the upper surface of the insulating film 26a or etching the metal thin film. The channel CA1 is made by applying the organic semiconductor material from above the source electrode SE1 and the drain electrode DE1. The source electrode SE1, the drain electrode DE1, and the channel CA1 are located above the gate electrode GE1.

As shown in FIG. 7, the relay electrode RE1 extends from the source electrode SE1 toward one side (+X side) in the first direction.

As shown in FIG. 5, the adhesive layer 27 is disposed on the upper surface of the insulating film 26b. For example, the adhesive layer 27 is a so-called double-sided tape. While not shown, in the adhesive layer 27, adhesive layers are provided on both surfaces of the base material. One of the adhesive layers in the adhesive layer 27 is adhered to the insulating film 26b.

The support substrate 28 has flexibility. The support substrate 28 is formed of a material having electric insulation on at least an outer surface. In the embodiment, the support substrate 28 is formed of a synthetic resin film having electric insulation such as polyethylene terephthalate, polyimide, or the like. For example, a thickness of the support substrate 28 is 50 μm. Further, the support substrate may be formed of a stainless foil or the like provided with an insulation coating on all outer surfaces and an inner surfaces of the through-hole.

The support substrate 28 is provided on the main substrate 21. More specifically, the support substrate 28 is disposed on the upper surface of the adhesive layer 27. The support substrate 28 is adhered to the other adhesive layer in the adhesive layer 27.

A through-hole (through-hole) H1 passing through the insulating film 26b, the adhesive layer 27, and the support substrate 28 is formed in the insulating film 26b, the adhesive layer 27, and the support substrate 28. The contact hole CH1 is disposed in the through-hole H1.

Further, a part of the contact hole CH1 may be disposed in the through-hole H1.

As shown in FIG. 5 and FIG. 6, the variable resistance part 24, the relay electrodes RE2 and RE3, and the insulating film 26c are formed on the upper surface of the support substrate 28. The variable resistance part 24 is provided on a first surface 28a of the support substrate 28 opposite to the main substrate 21. Hereinafter, a surface opposite to the first surface 28a of the support substrate 28 is referred to as a second surface 28b.

The insulating film 26c covers the variable resistance part 24 and the relay electrodes RE2 and RE3 from above. The relay electrode RE2 and the relay electrode RE3 according to the embodiment is made by applying the same conductive material on the upper surface (the first surface 28a) of the support substrate 28.

The conductive material that constitutes the relay electrode RE2 and the relay electrode RE3 is, for example, the same as the conductive material that constitutes the source electrode SE1, the drain electrode DE1, the signal lines DL, and the relay electrode RE1.

As shown in FIG. 5, the relay electrode RE2 is connected to the relay electrode RE1 via the contact hole CH1 passing through the insulating film 26b in the thickness direction. As shown in FIG. 6, the connection part 24c of the variable resistance part 24 is connected to the relay electrode RE2. That is, the variable resistance part 24 of the embodiment is connected to the source electrode SE1 of the transistor 25 via the relay electrode RE2, the contact hole CH1, and the relay electrode RE1. The contact hole CH1 electrically connects the transistor 25 and the variable resistance part 24.

The relay electrode RE3 is connected to the connection part 24d of the variable resistance part 24.

As shown in FIG. 5, the insulating film 26c is provided on the first surface 28a of the support substrate 28. The insulating film 26c covers the variable resistance part 24, the relay electrodes RE2 and RE3, and the like.

The power electrode PL is formed on the upper surface of the insulating film 26c. The power electrode PL is made by, for example, applying the same conductive material as the material of each electrode described above on the upper surface of the insulating film 26c or etching the metal thin film. The power electrode PL is connected to the relay electrode RE3 via the contact hole CH2 passing through the insulating film 26c in the thickness direction. That is, the variable resistance part 24 according to the embodiment is connected to the power electrode PL via the relay electrode RE2 and the contact hole CH2.

In addition, the source electrode SE1 according to the embodiment is connected to the power electrode PL via the variable resistance part 24, the relay electrode RE2 and the contact hole CH2.

Here, in FIG. 5, an axis O1 along the first surface 28a of the support substrate 28 is defined. In this example, the axis O1 is along the second direction. Further, the axis may be along the first direction. The axis O1 is preferably disposed on the lower surface of the adhesive layer 27.

A cross sectional secondary moment around the axis O1 of the main substrate 21 and the insulating films 26a and 26b as a whole is defined as l₁. A cross sectional secondary moment around the axis O1 of the adhesive layer 27, the support substrate 28 and the insulating film 26c is defined as l₂. Here, the cross sectional secondary moment l₁ and the cross sectional secondary moment l₂ are preferably equal to each other. Here, the phrase that the cross sectional secondary moment l₁ and the cross sectional secondary moment l₂ are equal to each other means that a value of (l₁/l₂) is 0.9 or more and 1.1 or less. The value of (l₁/l₂) is preferably 0.95 or more and 1.05 or less.

That is, the cross sectional secondary moment around the axis O1 of the configuration disposed below the lower surface of the adhesive layer 27 as a whole (hereinafter, referred to as a lower configuration) and the cross sectional secondary moment around the axis O1 of the configuration disposed above the lower surface of the adhesive layer 27 as a whole (hereinafter, referred to as an upper configuration) are preferably equal to each other.

The lower configuration and the upper configuration are preferably formed of the same material and have the same thickness.

The wiring part 40 may be a plurality of wire lines bundled parallel to each other in a flat ribbon shape. Each of the wire lines has flexibility. The wiring part 40, like the sensor main body 20, forms a film-like wiring made of a conductive material such as gold, silver, copper, aluminum, nickel-phosphorus, conductive polymer, or the like, on a substrate with flexibility, and may be coated with an insulating film.

The wiring part 40 extends from the sensor main body 20. The wiring part 40 electrically connects the sensor main body 20 and the controller 30. While not shown, the wiring part 40 has a plurality of first wirings, a plurality of second wirings, a wiring for a power supply, and a wiring for the ground GND (earth).

The plurality of first wirings are connected to the plurality of (eight) scan lines SL, respectively, to extend to the controller 30. The plurality of second wirings are connected to the plurality of (eight) signal lines DL, respectively, to extend to the controller 30.

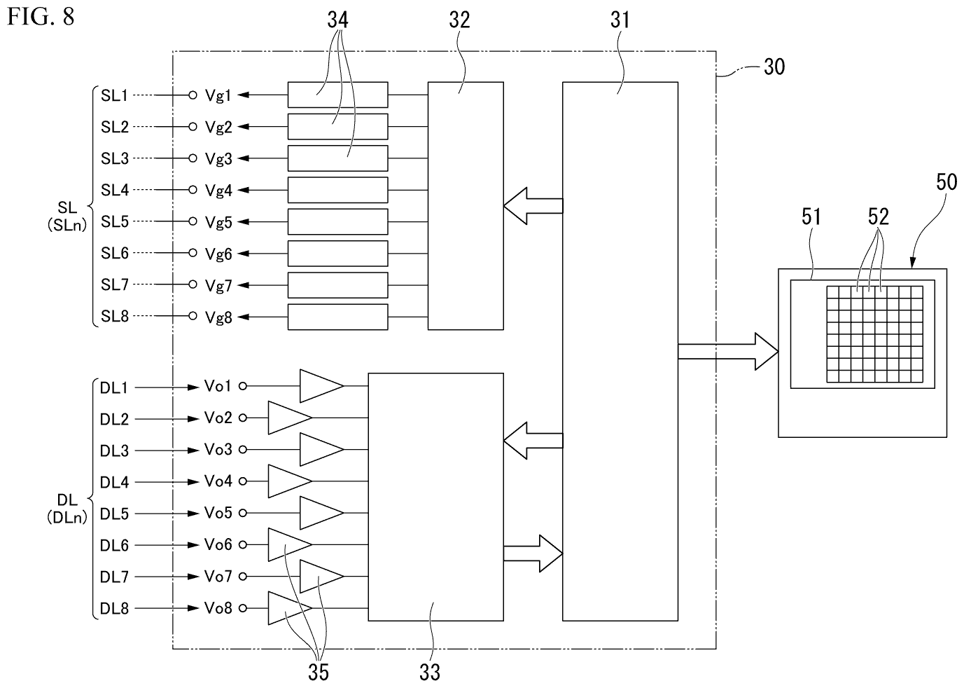

The controller 30 is connected to the sensor main body 20 via the wiring part 40. As shown in FIG. 8, the controller 30 has a scan line driving circuit 32, an 8-channel (8ch) AD converter circuit 33, and a microcomputer 31.

The plurality of scan lines SL1 to SL8 are connected to the scan line driving circuit 32. The scan line driving circuit 32 outputs a pulse-large scanning signal of a logic level (a 5V system or a 3V system) to any one of the plurality of scan lines SL1 to SL8 in sequence. The scanning signal is shifted by a level shifter 34 connected between each of the scan lines SL1 to SL8 and the scan line driving circuit 32 such that gate potentials Vg1 to Vg8 respectively applied to the scan lines SL1 to SL8 become appropriate voltage levels corresponding to characteristics of the transistor 25.

When a scanning signal from the scan line driving circuit 32 is supplied to the scan lines SL via the level shifter 34 as a gate potential Vg, the gate potential Vg is supplied to the gate electrode GE1 connected to the scan lines SL. Accordingly, the transistor 25 turns ON, and current flows from the source electrode SE1 to the drain electrode DE1 via the channel CA1.

A voltage obtained by amplifying each of output voltages Vo1 to Vo8 of the plurality of signal lines DL1 to DL8 using an amplifier 35 is applied to each channel of the 8ch AD converter circuit 33. The output voltages Vo1 to Vo8 are partial potentials expressed by a product of a current value determined as described below and a resistance value of fixed resistance part Ron (n=1 to 8) as shown in a circuit configuration of FIG. 4. The current value is determined by serial resistance values of the variable resistance part 24 connected to the power supply voltage Vcc applied between the power electrode PL and the ground GND, an ON resistance part between the drain and the source of the transistor 25 in the ON state, and the fixed resistance part Ron (n=1 to 8).

Further, the fixed resistance part Ron (n=1 to 8) may be connected to the variable resistor and the fixed resistor in series in order to adjust characteristics of ON resistance of the variable resistance part 24 and the transistor 25.

Here, the resistance value of the variable resistance part 24 changes as the strain (expansion and contraction of the variable resistance part 24 due to a curve of the main substrate 21) occurs. For this reason, an output voltage Vo that is a partial potential applied to the fixed resistance part Ro changes according to a variation in resistance value of the variable resistance part 24.

When the resistance value of the variable resistance part 24 is increased, since the voltage value applied to the fixed resistance part Ro is relatively reduced, the output voltage Vo is reduced. Meanwhile, when the resistance value of the variable resistance part 24 is reduced, since the voltage value applied to the fixed resistance part Ro is relatively increased, the output voltage Vo is increased. Accordingly, a variation of the resistance value of the variable resistance part 24 from the value of the output voltage Vo can be obtained, and the strain occurred in the sensor elements 23 can be detected.

Further, when the main substrate 21 is entirely and locally flat, even in a no-strain state in which the variable resistance part 24 does not expand and contract in the second direction, the variable resistance part 24 has a fixed resistance value. The output voltage Vo (Vo1 to Vo8) generated by the resistance value of the variable resistance part 24 in the no-strain state are stored in a memory of the microcomputer 31 in advance as a digital value corresponding to an initial voltage value (initial value) upon no-strain.

The output voltages Vo1 to Vo8 are amplified by the amplifier 35 and input to the AD converter circuit 33. The AD converter circuit 33 converts each of the output voltages Vo1 to Vo8, which were input, into digital data. The AD converter circuit 33 outputs the converted digital data to the microcomputer 31 on the basis of the instruction from the microcomputer 31.

The AD converter circuit 33 includes, for example, an analog multiplexer circuit configured to select one input signal from analog input signals for 8 channels. The AD converter circuit 33 converts analog values of the output voltages Vo1 to Vo8 input from the signal lines DL1 to DL8 into digital values in sequence.

The microcomputer 31 sends the instruction to the scan line driving circuit 32, and supplies the gate potentials Vg1 to Vg8 to the plurality of scan lines SL1 to SL8 in sequence. The microcomputer 31 sends the instruction to the AD converter circuit 33 according to the timing when the gate potentials Vg1 to Vg8 are supplied to the scan lines SL1 to SL8, respectively, and acquires the output voltages Vo1 to Vo8 from the signal lines DL1 to DL8 in sequence.

Accordingly, the output voltage Vo according to all the sensor elements 23 included in the sensor part 22 can be acquired. Accordingly, from the value of each of the output voltages Vo, the change from the initial value of the resistance value of the variable resistance part 24 in each of the sensor elements 23 can be obtained, and the strain of each of the sensor elements 23 can be detected.

The microcomputer 31 outputs the acquired data to a display device 50. The display device 50 displays, for example, information of the strain generated in the sensor main body 20 on a display screen 51.

A square frame 52 corresponding to each of, for example, the 64 sensor elements 23 is displayed on the display screen 51 in a matrix of 8×8. The display device 50 can display distribution of the strain generated in the sensor main body 20 by changing color in each frame 52 displayed on the display screen 51 according to the size of the strain generated in each of the sensor elements 23.

Further, when each of the square frames 52 arranged in a matrix of 8×8 is displayed by a 3-dimensional (3D) bar graph as a display format and each of the 64 sensor elements 23 are entirely in the no-strain state, the height of the bar graph for each frame 52 may be set to the fixed value (initial height). Then, the bar graph of the frame 52 corresponding to some of the 64 sensor elements 23 in which the strain occurs may be displayed such that the height varies from the initial height according to the degree of the strain (a curvature of that part of the main substrate 21).

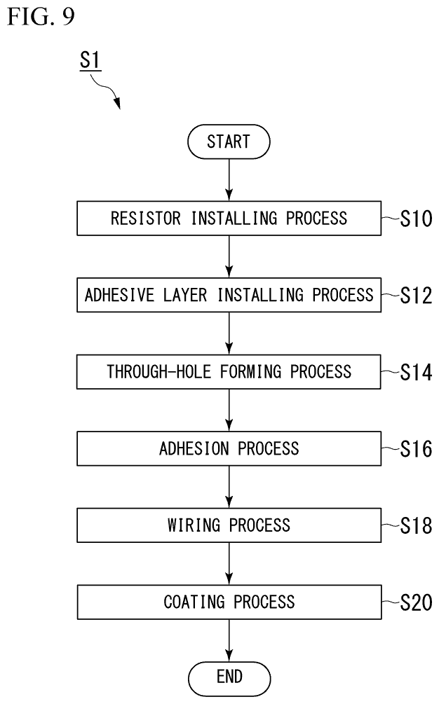

Next, in the method for manufacturing the flexible sensor 10 configured as above, in particular, description will focus on the method for manufacturing the sensor main body 20. FIG. 9 is a flowchart showing a manufacturing method S1 of the embodiment.

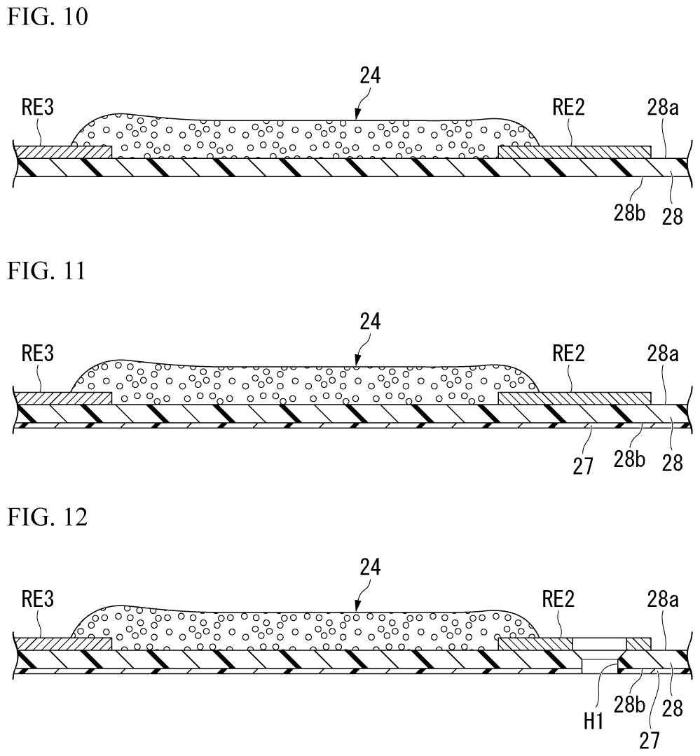

First, as shown in FIG. 10, the relay electrodes RE2 and RE3 are formed on the first surface 28a of the support substrate 28 by applying conductive ink or the like in advance.

In a resistor installing process (step S10 shown in FIG. 9), the variable resistance part 24 is provided on the first surface 28a of the support substrate 28. The variable resistance part 24 is formed by screen printing or the like. When the resistor installing process S10 is terminated, the method proceeds to step S12.

Next, as shown in FIG. 11, in an adhesive layer installing process S12, the adhesive layer 27 is provided on the second surface 28b of the support substrate 28. More specifically, the other adhesive layer of the adhesive layer 27 is adhered to the second surface 28b of the support substrate 28. The adhesive layer installing process S12 is performed after the resistor installing process S10. When the adhesive layer installing process S12 is terminated, the method proceeds to step S14.

Next, as shown in FIG. 12, in a through-hole forming process S14, the through-hole H1 passing through the support substrate 28 and the adhesive layer 27 is formed. The through-hole H1 may pass through the relay electrode RE2. For example, the through-hole H1 is formed by a laser beam. The through-hole forming process S14 is a process performed between the adhesive layer installing process S12 and an adhesion process S16, which will be described below.

When the through-hole forming process S14 is terminated, the method proceeds to step S16.

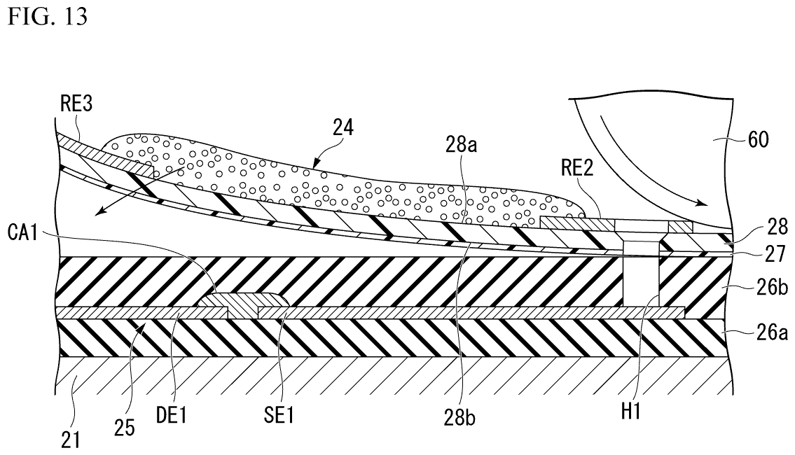

Next, as shown in FIG. 13, in the adhesion process S16, the adhesive layer 27 is adhered to the main substrate 21. More specifically, one adhesive layer of the adhesive layer 27 is adhered to the insulating film 26b. For example, a roller 60 is used to attach the adhesive layer 27. Further, the through-hole H1 is formed at a position of the insulating film 26b corresponding to the through-hole H1 of the support substrate 28 in advance.

For example, an alignment mark or the like provided on both the substrates 21 and 28 is used for alignment of the main substrate 21 and the support substrate 28. The adhesion process S16 is a process performed after the adhesive layer installing process S12 and the through-hole forming process S14.

When the adhesion process S16 is terminated, the method proceeds to step S18.

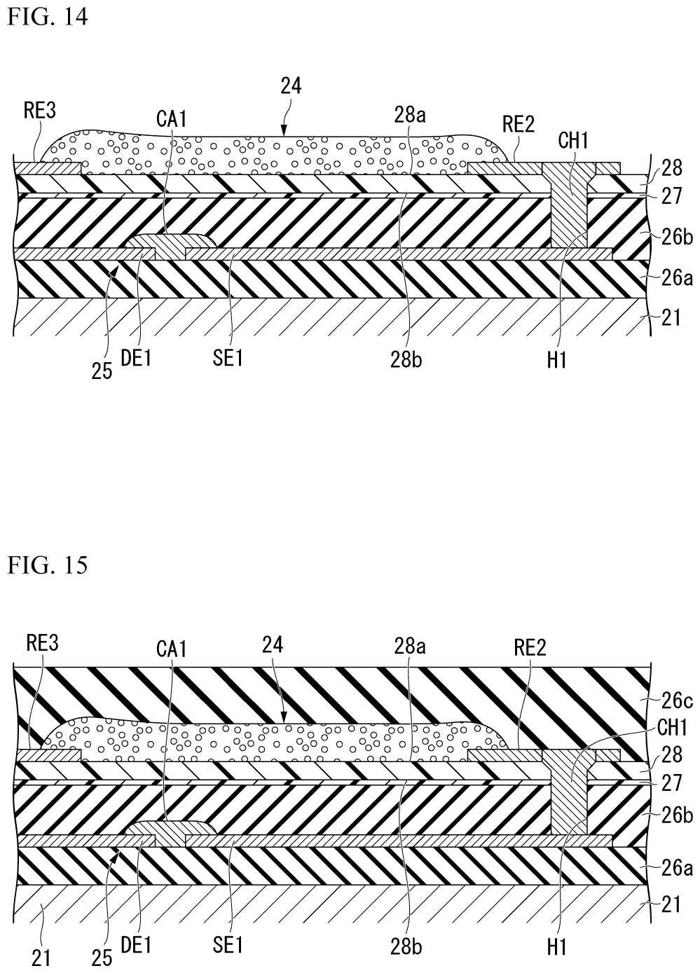

Next, as shown in FIG. 14, in a wiring process S18, the transistor 25 and the variable resistance part 24 provided on the main substrate 21 are electrically connected by the contact hole CH1 through the through-hole H1. For example, the contact hole CH1 is formed by injecting silver paste into the through-hole H1 and heating the silver paste. The wiring process S18 is a process performed after the adhesion process S16.

When the wiring process S18 is terminated, the method proceeds to step S20.

Next, as shown in FIG. 15, in a coating process S20, the insulating film 26c configured to cover the variable resistance part 24 is provided on the first surface 28a of the support substrate 28. Here, it is preferable to determine a material, a thickness, and the like, of the insulating film 26c such that the cross sectional secondary moment l₁ and the cross sectional secondary moment l₂ are equal to each other.

When the coating process S20 is terminated and the power electrode PL or the like is formed as appropriate, all the processes of the manufacturing method S1 are terminated, and the sensor main body 20 is manufactured. The flexible sensor 10 is manufactured by connecting the wiring part 40 and the controller 30 to the sensor main body 20.

In the flexible sensor and the manufacturing method in the related art, the variable resistance part is directly formed on a main substrate by screen printing or the like. In general, the main substrate is configured by laminating a plurality of layers (films). For this reason, when a screen mask for screen printing or the like is removed from the main substrate, there is a risk of damage to the main substrate due to the force being applied to the main substrate and peeling off the plurality layers.

On the other hand, in the flexible sensor 10 of the embodiment, for example, before the main substrate 21 and the support substrate 28 are laminated, the variable resistance part 24 is provided on the first surface 28a of the support substrate 28 by screen printing or the like. Since the force is applied to the support substrate 28 when removing the screen mask, etc., the main substrate 21 is unlikely to be damaged.

After that, the support substrate 28 is attached to the main substrate 21 or the like, the flexible sensor 10 is manufactured. Accordingly, it is possible to manufacture the flexible sensor 10 while suppressing damage to the main substrate 21.

In general, when the transistor is deformed, the resistance of the transistor changes according to the deformation. Since the flexible sensor 10 includes the support substrate 28, compared to the case where the flexible sensor 10 does not include the support substrate 28, the transistor 25 is located at the center of the strain of the flexible sensor 10. For this reason, when the flexible sensor 10 is bent, the transistor 25 is located near the center of the strain, making it difficult for the transistor 25 to deform. Accordingly, when the flexible sensor 10 is bent, the resistance value of the variable resistance part 24 can be measured accurately by measuring the resistance of the variable resistance part 24 using the transistor 25.

Since the flexible sensor 10 includes the support substrate 28 on which the variable resistance part 24 is provided, compared to the case in which the flexible sensor 10 does not include the support substrate 28, the variable resistance part 24 becomes farther from the center of the strain, and the deformation of the variable resistance part 24 becomes larger when the flexible sensor 10 is bent. Accordingly, the bending (strain) of the flexible sensor 10 can be measured with high accuracy.

For example, the flexible sensor 10 (the sensor main body 20) can be used to detect human motions. The flexible sensor 10 can be used by attaching it directly to the human skin, or it can be attached to something worn by the user, such as clothes or shoes.

For example, the flexible sensor 10 may be attached to the back of the hand or the upper arm for use, and finger movements may be indirectly detected based on the sensing result of the movement of the back of the hand or the upper arm.

In addition, in the manufacturing method S1 of the embodiment, the variable resistance part 24 is provided on the first surface 28a of the support substrate 28 by screen printing or the like in the resistor installing process S10. Since the force is applied to the support substrate 28 when removing the screen mask, etc., the main substrate 21 is unlikely to be damaged.

After the resistor installing process S10, the adhesive layer 27 is provided on the second surface 28b of the support substrate 28 in the adhesive layer installing process S12. Then, in the adhesion process S16, the adhesive layer 27 is attached to the main substrate 21, and the flexible sensor 10 is manufactured. Accordingly, it is possible to manufacture the flexible sensor 10 while suppressing damage to the main substrate 21.

In the manufacturing method S1, the same effect as the flexible sensor 10 can be exhibited.

The flexible sensor 10 includes the contact hole CH1 configured to electrically connect the transistor 25 and the variable resistance part 24 and disposed in the through-hole H1. In addition, in the manufacturing method S1, the through-hole H1 is formed in the through-hole forming process S14, and the transistor 25 and the variable resistance part 24 are electrically connected by the contact hole CH1 in the wiring process S18. Accordingly, the transistor 25 and the variable resistance part 24 can be electrically connected by the contact hole CH1 disposed in the through-hole H1 passing through the support substrate 28.

When the cross sectional secondary moment l₁ and the cross sectional secondary moment l₂ are equal to each other, the transistor 25 is located closer to the center of the strain. Accordingly, the transistor 25 becomes more difficult to deform, and the bending of the flexible sensor 10 can be measured with higher precision.

Hereinabove, while the embodiment of the present invention has been described in detail with reference to the accompanying drawings, the specific configuration is not limited to the embodiment, and includes modifications, combinations, deletion, and the like, of the configuration without departing from the scope of the present invention.

For example, in the embodiment, the adhesive layer may be a layer made of hot melt, ultraviolet (UV) cured resin, thermosetting resin, or the like. When the adhesive layer is the UV cured resin, after the adhesive layer 27 is adhered to the main substrate 21 in the adhesion process S16, the adhesive layer disposed between the insulating film 26b and the support substrate 28 is irradiated with ultraviolet rays.

The flexible sensor 10 may not include the adhesive layer 27, the insulating film 26c, the contact hole CH1, CH2, the wiring part 40, and the controller 30.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A flexible sensor comprising:
a main substrate having flexibility;
a transistor over the main substrate;
a support substrate over the transistor, wherein the support substrate has flexibility and at least an outer surface of the support substrate comprises a material having electric insulation; and
a variable resistance part over a first surface which is an upper surface of the support substrate, in which a resistance value of the variable resistance part changes according to strain of the variable resistance part.

2. The flexible sensor according to claim 1, further comprising,
a through-hole passing through the support substrate, and
a wiring electrically connected with the transistor and the variable resistance part, wherein at least a part of the wiring is disposed in the through-hole.

3. The flexible sensor according to claim 1, further comprising,
a coating member over the variable resistance part, wherein the coating member covers the variable resistance part,
wherein, in a cross sectional secondary moment around an axis along the first surface, a cross sectional secondary moment of the main substrate and cross sectional secondary moments of the support substrate and the coating member are equal to each other.

4. A method for manufacturing a flexible sensor comprising:
a process of providing a variable resistance part, over a first surface of a support substrate which has flexibility and at least an outer surface of the support substrate comprises a material having electric insulation, which has a resistance value that changes according to strain of the variable resistance part;
a process of forming a transistor over a main substrate having flexibility;
a process of providing an adhesive layer over a second surface of the support substrate opposite to the first surface after the process of providing the variable resistance part; and
a process of attaching the adhesive layer to the main substrate on a side that the transistor is formed after the process of providing the adhesive layer.

5. The method for manufacturing the flexible sensor according to claim 4, further comprising:
a process of forming a through-hole, which passes through the support substrate and the adhesive layer, between the process of providing the adhesive layer and the process of attaching the adhesion layer; and
a process of electrically connecting the transistor and the variable resistance part using a wiring through the through-hole after the process of attaching the adhesive layer.

6. The method for manufacturing the flexible sensor according to claim 4, further comprising:
a process of providing a coating member, which covers the variable resistance part over the first surface of the support substrate,
wherein, in a cross sectional secondary moment around an axis along the first surface, a cross sectional secondary moment of the main substrate and a cross sectional secondary moment of the support substrate and the coating member are equal to each other.
